(19) United States
(12) Patent Application Publication
(10) Pub. No.: US 2005/0170661 A1
(43) Pub. Date: Aug. 4, 2005

(54) Method of forming a trench structure

(75) Inventors: Laertis Economikos, Wappingers Falls, NY (US); Klaus Hummler, Apex, NC (US)

Correspondence Address: SCHMEISER, OLSEN + WATTS, 3 LEAR JET LANE, SUITE 201, LATHAM, NY, 12110, US

(73) Assignees: International Business Machines Corporation, Armonk, NY (US); Infineon Technologies North America Corp, San Jose, CA (US)

(21) Appl. No.: 10/708,035

(22) Filed: Feb. 4, 2004

(51) Int. Cl. H01L 21/31

(52) U.S. Cl. 438/759

(57) ABSTRACT

A method of fabricating a filled trench structure, the method including: (a) forming a first set of trenches in a first region of a substrate and forming a second set of trenches in a second region of the substrate, trenches in the first set of trenches having a higher aspect ratio than the trenches in the second region; (b) depositing a fill material in the first and second set of trenches and on a top surface of the substrate, the fill material completely filling the trenches; (c) removing an upper portion of the fill material; and (d) removing, using a planarization process, all fill material from the top surface of the substrate, a top surface of the fill material in the first and second sets of trenches co-planer with the top surface of the substrate.

### BACKGROUND OF INVENTION

The present invention relates to the field of integrated circuit manufacture; more specifically, it relates to method for forming a trench structure in an integrated circuit.

Trench structures formed in semiconductor substrates are used in integrated circuits for a number of reasons. In one example trench structures filled with dielectric material are used to isolate various devices from one another. In a second example, trench structures filled with conductive materials are used as capacitors. Part of the fabrication process of some trench structures is a chemical-mechanical polish (CMP) or fixed abrasive grinding step to remove excess fill material from the surface of the substrate. However as the aspect ratio (depth divided by width) of trenches increases, it becomes more difficult to uniformly remove this excess fill material from both regions of high-density high aspect ratio trenches and regions of low-density trenches or wide trenches simultaneously. The non-uniformities can lead to poor feature size control in subsequent photolithographic and other process steps. Therefore, there is a need for a method to uniformly remove this excess fill material from both regions of high-density high aspect ratio trenches and regions of low-density trenches or wide trenches simultaneously.

### SUMMARY OF INVENTION

A first aspect of the present invention is a method of fabricating a filled trench structure, comprising: (a) forming a first set of trenches in a first region of a substrate and forming a second set of trenches in a second region of the substrate, trenches in the first set of trenches having a higher aspect ratio than the trenches in the second region; (b) depositing a fill material in the first and second set of trenches and on a top surface of the substrate, the fill material completely filling the trenches; (c) removing an upper portion of the fill material; and (d) removing, using a planarization process, all fill material from the top surface of the substrate, a top surface of the fill material in the first and second sets of trenches co-planer with the top surface of the substrate.

A second aspect of the present invention is a method of fabricating a filled trench structure, comprising: (a) forming a planarization stop layer on a top surface of a substrate; (b) forming a first set of trenches in a first region of the planarization stop layer and the substrate and forming a second set of trenches in a second region of the planarization stop layer and the substrate, trenches in the first set of trenches having a higher aspect ratio than the trenches in the second region; (c) depositing a fill material in the first and second set of trenches and on a top surface of the planarization stop layer, the fill material completely filling the trenches; (d) removing an upper portion of the fill material; and (e) removing, using a planarization process, all fill material from the top surface of the planarization stop layer, a top surface of the fill material in the first and second sets of trenches co-planer with the top surface of the planarization stop layer.

### BRIEF DESCRIPTION OF DRAWINGS

The features of the invention are set forth in the appended claims. The invention itself, however, will be best understood by reference to the following detailed description of an illustrative embodiment when read in conjunction with the accompanying drawings, wherein:

FIG. 1 is a partial cross-sectional view of a semiconductor substrate prior to a trench formation process;

FIG. 2 is a partial cross-sectional view of the semiconductor substrate after a trench formation process;

FIG. 3 is a partial cross-sectional view of the semiconductor substrate after a trench fill process, but before a planarization process;

FIG. 4 is a partial cross-sectional view of the semiconductor substrate after a planarization process and illustrates non-uniform planarization of fill material;

FIGS. 5A and 5B are partial cross-sectional views of the semiconductor substrate illustrating preparation of the substrate according to a first embodiment of the present invention prior to planarization;

FIGS. 6 is a partial cross-sectional view of the semiconductor substrate illustrating preparation of the substrate according to a second embodiment of the present invention prior to planarization; and

FIG. 7 is a partial cross-sectional view of the semiconductor substrate after preparation of the substrate according to the present invention and after planarization.

### DETAILED DESCRIPTION

The term trench as used in the present invention is intended to encompass shallow trenches as well as deep trenches. The term trench isolation is intended to encompass deep trench isolation as well as shallow trench isolation. For the purposes of the present invention, the aspect ratio of a trench is defined as the depth of the trench into the substrate divided by the width of the trench at the surface of the substrate or the depth of the trench into the substrate from the top surface of any layers formed on top of the substrate, if present divided by the width of the trench at the top surface of any layers formed on the top surface of the substrate, if present by. For the purposes of the present invention the term wafer may be substituted for the term substrate.

The present invention will be described using an exemplary trench isolation scheme. However, the invention is not limited to trench isolation as will be made cleared infra.

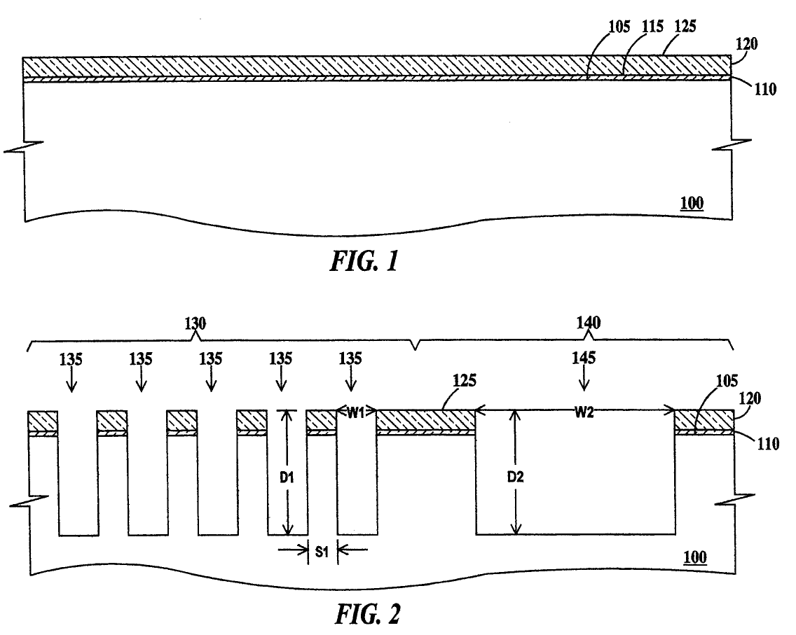

FIG. 1 is a partial cross-sectional view of a semiconductor substrate 100 prior to a trench formation process. In FIG. 1, semiconductor substrate 100 has a top surface 105. Formed on top surface 105 is a silicon oxide layer 110 having a top surface 115. Formed on top surface 115 is a silicon nitride layer 120 having a top surface 125. Substrate 100 may be a bulk monocrystalline silicon substrate. Substrate 100 may be a silicon-on-insulator (SOI) substrate, in which case only the uppermost silicon layer is illustrated in FIG. 1. Substrate 100 may be a bulk monocrystalline silicon substrate on which an epitaxial layer of silicon has been formed, in which case the epitaxial layer is not distinguished from the bulk silicon substrate in FIG. 1. In one example, silicon oxide layer 110 is less than 100 Å thick and silicon nitride layer is about 500 to 1000 Å thick. In the example of trench isolation, silicon oxide layer 110 may be termed a pad oxide and silicon nitride layer 120 may be termed a pad nitride.

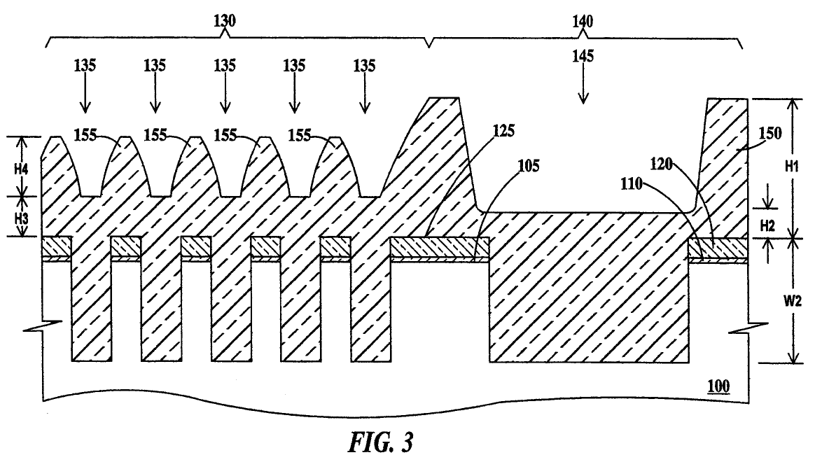

FIG. 2 is a partial cross-sectional view of semiconductor substrate 100 after a trench formation process. In FIG. 2, a first trench region 130 includes a multiplicity of trenches 135 and a second trench region 140 including a trench 145. There may be more or less trenches 135 in first trench region 130 and more trenches 145 in second trench region 140 than illustrated in FIG. 2. In one example, trenches 135 and 145 are formed by etching a pattern in silicon oxide layer 110 and silicon nitride layer 120 and then isotropically etching exposed regions of substrate 100 using for example, a reactive ion etch (RIE) process.

Trenches 135 have a depth of D1 measured from top surface 125 of silicon nitride layer 120 and a width of W1 measured at top surface 125. Trench 145 has a depth of D2 measured from top surface 125 of silicon nitride layer 120 and a width of W2 measured at top surface 125. Generally, D1 and D2 are about equal, but it is not unusual for D2 to be greater than D1 depending upon the exact RIE process used to form trenches 135 and 145. If silicon oxide layer 110 and silicon nitride layer 120 are removed as part of the trench formation process or after the trench formation process but before a trench fill process, then D1, D2, W1 and W2 are measured from top surface 105 of substrate 100. Trenches 135 are spaced apart a distance S1. It is possible for S1 and W1 to be about equal, especially if both are defined by photolithographic masks having lines and spaces of minimum printable dimensions in regions of the mask corresponding to first region 130.

In one example, D1 is greater than about 4000 Å, D2 is about equal to D1, W1 and S1 are both less than about 1300 Å, W2 is about 5 times W1. In another example, the aspect ratio of trenches 135 (D1/W1) is about greater than about 3:1 and the aspect ratio of trench 145 is less than about 3:1. In one example, region 130 is a memory cell array region of an integrated circuit memory and region 140 is a support circuit region.

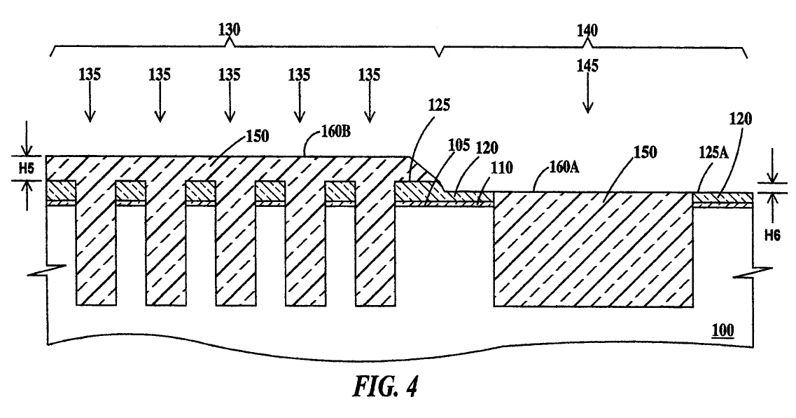

FIG. 3 is a partial cross-sectional view of semiconductor substrate 100 after a trench fill process, but before a planarization process. In FIG. 3 a fill layer 150 of fill material has been deposited on substrate 100 and silicon nitride layer 120. The height of fill layer 150 is H1. Generally H1 is greater than D1 and D2 (see FIG. 2) by a predetermined amount. The height of fill layer 150 over trench 145 in second region 140 is H2. The height of fill layer 150 over trenches 135 in first fill region 130 is H3. In one example, H3 is greater than H2. Fill layer 150 forms hats 155 aligned between trenches 135 in first region 130. Hats 155 have a height H4. H1, H2, H3 are measured from top surface 125 of silicon nitride layer 120. If silicon oxide layer 110 and silicon nitride layer 120 are removed as part of the trench formation process or after the trench formation process but before a trench fill process, then H1, H2 and H3 are measured from top surface 105 of substrate 100. H4 is measured relative to the height H3 of fill layer 150 over trenches 135.

In one example, H1 is equal to H2 (see also FIG. 2) plus at least 200 Å. In another example, H3 greater than H2, and H1 is greater than H3 plus H4. In still another example, H2 is about 8000 Å, H1 is about 9200 Å, H2 is 1400 Å, H3 is about 2100 Å and H4 is about 3600 Å and about 9200 Å of fill layer 150 have been deposited.

In the example of a trench isolation scheme, fill layer 150 comprises a high-density plasma oxide (HDP), a low-pressure chemical vapor deposition (LPCVD) oxide such as tetraethoxysilane (TEOS), LPCVD silicon nitride or other deposited dielectrics such as bis(tertiary-butylamine)silane (BTBAS).

In the example that trenches 135 are trench capacitors, fill layer 150 comprises a thin layer of conformal insulator such as thermal oxide and a fill layer of N-doped, P-doped or un-doped polysilicon.

In another example, substrate 100 may be a dielectric layer, fill layer 150 may include a metal such as tungsten, copper or aluminum and trenches 135 and 145 may be vias or wires in wiring levels of an integrated circuit.

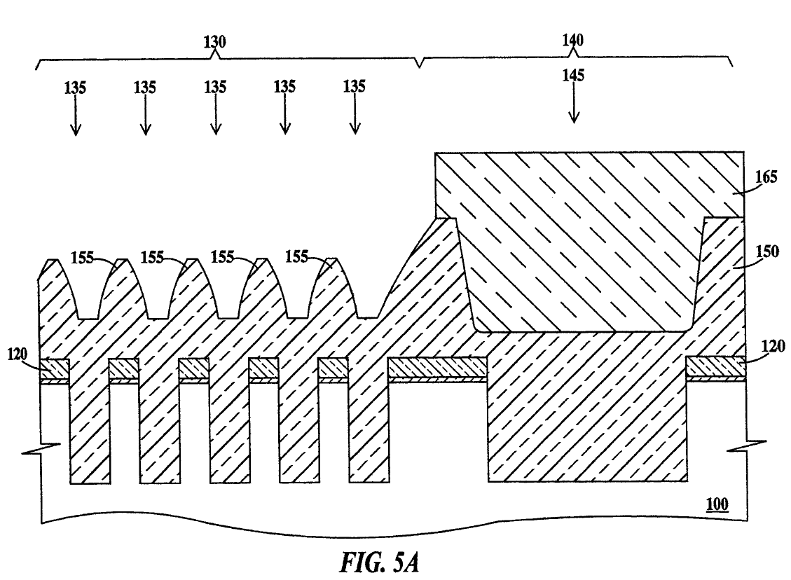

FIG. 4 is a partial cross-sectional view of semiconductor substrate 100 after a planarization process and illustrates non-uniform planarization of fill layer 150. In FIG. 4, a planarization process has been performed. Planarization processes include CMP and fixed abrasive grinding. In second region 140, the planarization processes removed all fill layer 150 from above top surface 125A of silicon nitride layer 120 leaving a top surface 160A of fill layer 150 in second region 140 and top surface 125A of silicon nitride layer 120 substantially co-planer. In first region 130, a thickness H5 of fill layer 150 remains above top surface 125 of silicon nitride layer 120 and a top surface 160B of fill layer 150 in first region 130 and top surface 125 of silicon nitride layer 120 therefore not planer. Note that top surface 125A is lower than top surface 125 by a distance H6 since silicon nitride layer 125 is used as planarization stop layer and some over polish/over grinding is performed. In a CMP process, a polishing stop layer functions because it is harder than the material be removed and is abraded away slower, is more resistant chemically to the etchant (if any) contained in the polishing slurry or both. In a fixed abrasive grinding process, a grinding stop layer functions because it is harder than the material be removed and is abraded away slower.

Applicants have experimentally determined that the uneven fill removal occurs when the aspect ratio of trenches 135 in first region 130 is about 3:1 or greater while the aspect ratio of trench 145 in region 140 is less than about 3:1. Applicants have experimentally determined the higher the aspect ratio of trenches 135 the more pronounced the difference in fill removal by mechanical planarization. Applicants believe the difference in removal of fill layer 150 is not a function of the relative values of H1, H2, H3 and H4 as illustrated in FIG. 3, but of the relative volume of fill layer 150 in first and second regions 130 and 140. Applicants have further determined that over polishing/grinding in order to remove fill layer 150 from silicon nitride layer 120 in first region 130 results in total removal of the silicon nitride layer from region 140 resulting in a non-planar surface that negatively effects subsequent integrated circuit fabrication steps. Applicants have experimentally determined that at aspect ratios of about 5:1 or greater, manufacturability becomes an important issue, it becoming almost impossible to remove fill material from first region 130 without making the product non-functional.

In the example of trenches 135 and 145 being about 8000 Å deep, the aspect ratio of trenches 135 being about 5:1, the aspect ratio of trench 145 being less than 1:1 and fill layer 150 being about 9200 Å, H5 is about 200 Å and H6 is about 500 Å.

As mentioned supra, there are two planarization methods applicable to FIG. 4. The first is CMP, which utilizes an abrasive polishing/etching slurry introduced between a polishing wheel and the top surface of the substrates.

Abrasive particles in the slurry affect mechanical removal and chemical etchants in the slurry affect at least partial dissolution of the material abrasively removed from the top surface of the substrate as well as directly etching the top surface of the substrate. The second is fixed abrasive grinding which does not use a slurry, the abrasive being fixed to a web (a continuous belt), though water or other fluid may be introduced between the web and the top surface of the substrate.

In the example of HDP fill (or other oxide), a suitable CMP slurry is ceria based. In the example of tungsten, a suitable CMP slurry is alumina based. In the example of copper, a suitable CMP slurry is ferric chloride based. In the example of polysilicon, a suitable CMP slurry is based on a strong base such as alcoholic potassium hydroxide. A suitable fixed abrasive process for any of the examples supra utilizes a ceria coated web.

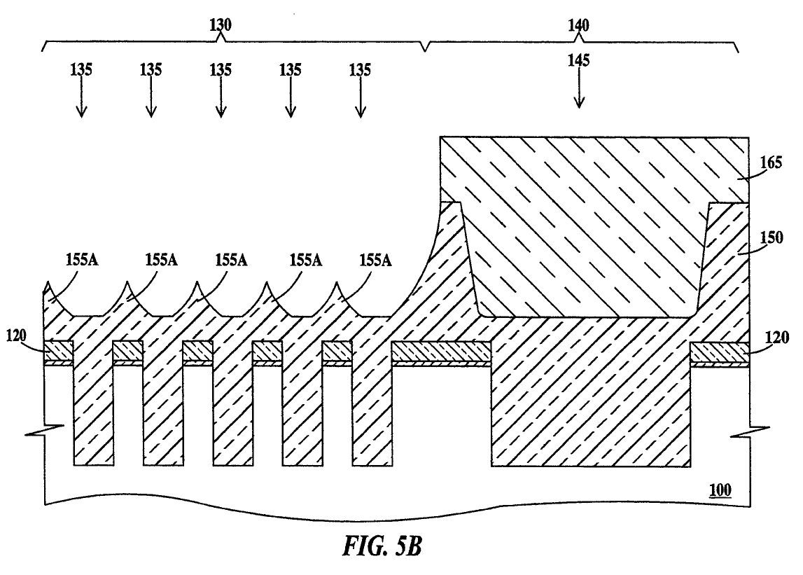

FIGS. 5A and 5B are partial cross-sectional views of semiconductor substrate 100 illustrating preparation of the substrate according to a first embodiment of the present invention prior to planarization. In FIG. 5A a photoresist mask 165 is formed over fill layer 150 in second region 140. Photomask 165 may be formed by any of several methods well known in the art. In FIG. 5B, a wet etch is performed, reducing the size of and increasing the distance between the tops of hats 155 of FIG. 5A to the size and spacing of hats 155A of FIG. 5B. Further the height of fill layer 150 over trenches 135 in first region 130 is also reduced. The goal of the wet etch is to equalize (as much as possible) the volume of fill layer 150 not contained in trenches 135 in first region 130 (i.e. the excess or overfill) and the volume of fill layer 150 not contained in trenches 145 in second region 140 (i.e. the excess or overfill). The amount of fill layer 150 removed by the wet etch need only be sufficient to result in exposure of silicon nitride layer 120 in both first region 135 and second region 145 nearly simultaneously after a short amount of over-polish or over-grinding. However, strict equalization of volumes of fill layer 150 to be removed in first region 130 and second region 140 though desirable, is not required. What is required is only that the volume of fill layer 150 in first region 130 be reduced. That said, the closer to equal volumes of fill layer 150 between first region 130 and second region 140 the more uniform the planarity of the surface from the first to the second region will be and less over polish or over grinding will be required. In applications where no planarization stop is used (i.e. no silicon nitride layer or the like), more uniformity in the volumes of fill layer 150 between first region 130 and second region 140 is a benefit. The amount of fill layer 150 removed can be measured in units of etch time or thickness of fill layer 150 removed.

In one example, the amount of fill material removed and time of the wet etch is experimentally pre-determined using test substrates to be an amount or time that clears fill layer 150 from over silicon nitride layer 120 in both first region 130 and second region 140 in a predetermined amount of CMP or grind time. In a second example, the thickness of fill material removed is between about 5 and 20% of the as deposited thickness of fill layer 150. In the example of trenches 135 and 145 being about 8000 Å deep, the aspect ratio of trenches 135 being about 5:1, the aspect ratio of trench 145 being less than 1:1 and fill layer 150 being about 9200 Å, a wet etch removing about 400 Å of fill layer 150 from first region 130 is used.

Examples of suitable wet etchants are dilute hydrofluoric acid and buffered hydrofluoric acid when fill material is an oxide. When fill material 150 is polysilicon, a suitable etchant is a strong base such as alcoholic potassium hydroxide. When fill material 150 is tungsten, a suitable etchant is peroxide based. When fill material 150 is copper, a suitable etchant is ferric chloride based. When fill material 150 is aluminum, a suitable etchant is an aqueous mixture of phosphoric and nitric acids. Other isotropic etches may be used.

It is possible to practice the present invention using dry etching such as RIE or plasma etching even though these etches tend to be anisotropic in nature (plasma etching less so). For example, oxides may be etched using fluorine-containing plasmas.

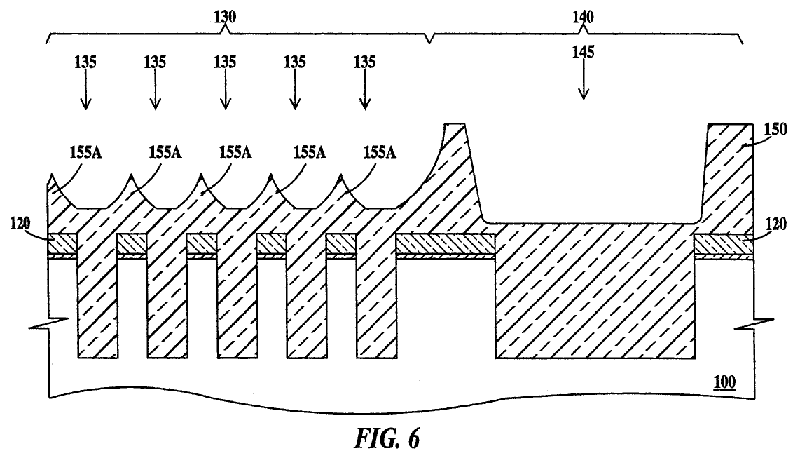

FIG. 6 is a partial cross-sectional view of semiconductor substrate 100 illustrating preparation of the substrate according to a second embodiment of the present invention prior to planarization. The major difference between the first and second embodiments of the present invention is that no masking step is performed in the second embodiment of the present invention. In FIG. 6, a wet etch is performed, reducing the size of and spacing between hats 155 of FIG. 3 to the size and spacing of hats 155A of FIG. 6 and reducing the height of fill layer 150 over silicon nitride layer 120 in second region 140. Further the thickness of fill layer 150 over trenches 135 and 140 is reduced as well. The goal of the wet etch is to equalize as much as possible the amount of fill layer 150 not contained in trenches 135 in first region 130 to the amount of fill layer 150 not contained in trenches 145 in second region 140. The amount of fill layer 150 removed by the wet etch need only be sufficient to result in exposure of silicon nitride layer 120 in both first region 130 and second region 140 after a short amount of over-polish or over-grinding. However, strict equalization of volumes of fill layer 150 to be removed in first region 130 and second region 140 though desirable, is not required, what is required is only that the volume of fill layer 150 in first region 130 be reduced relative to the volume of fill layer 150 in second region 140. That said, the closer to equal volumes of fill layer 150 between first region 130 and second region 140 the more uniform the planarity of the surface from the first to the second region will be and less over polish or over grinding will be required. In applications where no polish/grinding stop is used (i.e. no silicon nitride layer or the like), more uniformity in the volumes of fill layer 150 between first region 130 and second region 140 is a benefit. The amount of fill layer 150 removed can be measured in units of etch time or thickness of fill layer 150 removed.

In one example, the amount of fill material removed and time of the wet etch is experimentally pre-determined using test substrates to be an amount or time that clears fill layer 150 from over silicon nitride layer 120 in both first region 130 and second region 140 in a predetermined amount of CMP or grind time. In a second example, the thickness of fill material removed is between about 5 and 20% of the as deposited thickness of fill material 150. In the example of trenches 135 and 145 being about 8000 Å deep, the aspect ratio of trenches 135 being about 5:1, the aspect ratio of trench 145 being less than 1:1 and fill layer 150 being about 9200 Å the wet etch removes about 400 Å of fill layer 150 from first region 130.

Etchants and etchant processes are the same as described supra in reference to FIG. 5B.

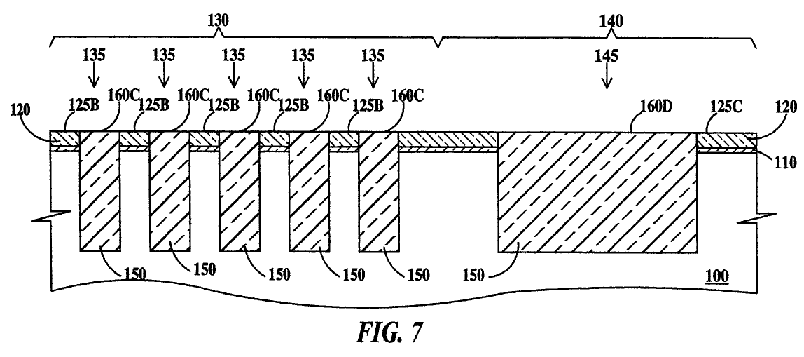

FIG. 7 is a partial cross-sectional view of semiconductor substrate 100 after preparation of the substrate according to the present invention and after planarization. For the first embodiment of the present invention, FIG. 7 illustrates the uniformity of CMP or fixed abrasive grinding after etching as described supra in reference to FIG. 5B, removal of mask 165 (see FIG. 5B) and the planarization as described supra in reference to FIG. 4. For the second embodiment of the present invention, FIG. 7 illustrates the uniformity of CMP or fixed abrasive grinding after etching as described supra in reference to FIG. 6 and the planarization as described supra in reference to FIG. 4.

In FIG. 7, top surfaces 160C of fill layer 150 in trenches 135 are co-planer with top surfaces 125B of silicon nitride layer 120 in first region 130 and a top surface 160D of fill layer 150 in trenches 145 are co-planer with a top surface 125C of silicon nitride layer 120 in second region 140.

The thickness of silicon nitride layer 120 in FIG. 7 is reduced from the thickness of silicon nitride layer 120 in FIGS. 5A or 6 due to over polishing or over grinding.

Thus, the present invention provides a method to uniformly remove excess fill material from both regions of high-density high aspect ratio trenches and regions of low-density trenches or wide trenches simultaneously.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

1. A method of fabricating a filled trench structure, comprising:
(a) forming a first set of trenches in a first region of a substrate and forming a second set of trenches in a second region of said substrate, trenches in said first set of trenches having a higher aspect ratio than said trenches in said second region;
(b) depositing a fill material in said first and second set of trenches and on a top surface of said substrate, said fill material completely filling said trenches;
(c) removing an upper portion of said fill material; and
(d) removing, using a planarization process, all fill material from said top surface of said substrate, a top surface of said fill material in said first and second sets of trenches co-planer with said top surface of said substrate.

2. The method of claim 1, wherein step (c) includes wet etching, dry etching, reactive ion etching or plasma etching of said fill material.

3. The method of claim 1, wherein step (c) includes chemical-mechanical polishing or fixed abrasive grinding said fill material.

4. The method of claim 1, further including:
between steps (b) and (c) forming a mask layer on said fill material said second region, wherein in step (c) fill material is only removed from said first region; and
between steps (c) and (d) removing said masking layer.

5. The method of claim 4, wherein step (c) removes about 5 to 20% of an as deposited thickness of said fill material.

6. The method of claim 1, wherein the aspect ratio of trenches in said first set of trenches is greater than about 3:1 and the aspect ratio of trenches in said second region is less than about 3:1.

7. The method of claim 1, wherein said first region is a memory cell array region and said second region is a support circuit region of an integrated circuit.

8. The method of claim 1, wherein said fill material is selected from the group consisting of: high-density plasma oxide, low-pressure chemical vapor deposition oxide, tetraethoxysilane oxide, silicon nitride, bis(tertiary-butylamine)silane, a thin layer of conformal insulator and a fill layer of N-doped, P-doped or undoped polysilicon, tungsten, copper or aluminum.

9. The method of claim 1, wherein the volume of fill material removed in step (c) is experimentally pre-determined to be a volume that allows removal in step (d) of all of said fill material from said top surface of said substrate in both said first and second regions in a predetermined amount of chemical-mechanical-polish or grind time.

10. The method of step 1, wherein step (c) removes about 5 to 20% of the as deposited thickness of said fill material.

11. A method of fabricating a filled trench structure, comprising:
(a) forming a planarization stop layer on a top surface of a substrate;
(b) forming a first set of trenches in a first region of said planarization stop layer and said substrate and forming a second set of trenches in a second region of said planarization stop layer and said substrate, trenches in said first set of trenches having a higher aspect ratio than said trenches in said second region;
(c) depositing a fill material in said first and second set of trenches and on a top surface of said planarization stop layer, said fill material completely filling said trenches;
(d) removing an upper portion of said fill material; and
(e) removing, using a planarization process, all fill material from said top surface of said planarization stop layer, a top surface of said fill material in said first and second sets of trenches co-planer with said top surface of said planarization stop layer.

12. The method of claim 11, wherein step (d) includes wet etching, dry etching, reactive ion etching or plasma etching of said fill material.

13. The method of claim 11, wherein step (e) includes chemical-mechanical polishing or fixed abrasive grinding of said fill material.

14. The method of claim 11, further including:
between steps (c) and (d) forming a mask layer on said fill material in said second region, wherein in step (d) fill material is only removed from said first region; and
between steps (d) and (e) removing said masking layer.

15. The method of claim 14, wherein step (d) removes about 5 to 20% of an as deposited thickness of said fill material.

16. The method of claim 11, wherein the aspect ratio of trenches in said first set of trenches is greater than about 3:1 and the aspect ratio of trenches in said second region is less than about 3:1.

17. The method of claim 11, wherein said first region is a memory cell array region and said second region is a support circuit region of an integrated circuit.

18. The method of claim 11, wherein said fill material is selected from the group consisting of: high-density plasma oxide, low-pressure chemical vapor deposition oxide, tetraethoxysilane oxide, silicon nitride, bis(tertiary-butylamine)silane, a thin layer of conformal insulator and a fill layer of N-doped, P-doped or undoped polysilicon, tungsten, copper or aluminum.

19. The method of claim 11, wherein the volume of fill material removed in step (d) is experimentally predetermined to be a volume that allows removal in step (e) of all of said fill material from said top surface of said substrate in both said first and second regions in a predetermined amount of chemical-mechanical-polish or grind time.

20. The method of step 11, wherein step (d) removes about 5 to 20% of the as deposited thickness of said fill material.
